(19) United States
(12) Patent Application Publication
(10) Pub. No.: US 2026/0324137 A1
(43) Pub. Date: Oct. 15, 2026

(54) SEMICONDUCTOR DEVICE AND MANUFACTURING METHOD THEREOF

(71) Applicant: ENNOSTAR CORPORATION, Hsinchu City (TW)

(72) Inventors: Hsiu-Mei CHOU, Hsinchu City (TW); Yu-Hung Lee, Hsinchu City (TW); Hsin-Chuan Wang, Hsinchu City (TW)

(21) Appl. No.: 19/578,507

(22) Filed: Mar. 25, 2026

(30) Foreign Application Priority Data
Mar. 28, 2025 (TW) 114112046

(51) Int. Cl. H10H 20/825; H10H 20/01; H10H 20/812

(52) U.S. Cl. CPC H10H 20/825; H10H 20/812; H10H 20/0137

(57) ABSTRACT

A semiconductor device includes a base layer, a first semiconductor structure on the base layer, and a transition structure between the base layer and the first semiconductor structure and including a first transition layer. The base layer includes nitrogen and aluminum. The first semiconductor structure includes AlₓGa₁₋ₓN, and the first transition layer includes Al_{y1}Ga_{1-y1}N, 0<x<1 and y1>x. The base layer has a first thickness T1, and the transition structure has a second thickness T2, T2>T1.

### CROSS-REFERENCE TO RELATED DISCLOSURES

This disclosure claims the right of priority of TW Disclosure No. 114112046 filed on Mar. 28, 2025, and the content of which is hereby incorporated by reference in its entirety.

### BACKGROUND

### Technical Field

The present application relates to a semiconductor technology, and more particularly to a semiconductor device and a manufacturing method thereof.

A conventional UVC LED may include an aluminum nitride (AIN) base layer and an aluminum gallium nitride (AlGaN) layer epitaxially grown thereon. AIN and AlGaN have different lattice constants. Therefore, when the AlGaN layer is epitaxially grown on the AIN base layer, epitaxial defects may arise due to lattice mismatch between the AlGaN layer and the AIN base layer.

Epitaxial defects can affect the material quality of AlGaN layer, the surface planarity of AlGaN layer may be degraded. If epitaxial defects propagate to a surface of AlGaN layer, cracks of AlGaN layer are formed. Degraded material quality of AlGaN layer causes the multiple-quantum-well (MQW) structure stacked above AlGaN layer to have more defects. Non-radiative recombination in the light-emitting diode increases with the defects in the MQW structure, thereby reducing the light output efficiency of the light-emitting diode.

### SUMMARY

A semiconductor device includes a base layer, a first semiconductor structure on the base layer, and a transition structure between the base layer and the first semiconductor structure and including a first transition layer. The base layer includes nitrogen and aluminum. The first semiconductor structure includes AlₓGa₁₋ₓN, and the first transition layer includes Al_{y1}Ga_{1-y1}N, 0<x<1 and y1>x. The base layer has a first thickness T1, and the transition structure has a second thickness T2, T2>T1.

### BRIEF DESCRIPTION OF THE DRAWINGS

To make the objects, features, and advantages of the present disclosure more readily understood, detailed descriptions of specific embodiments are provided below with reference to the accompanying drawings.

FIG. 1 shows the semiconductor structure of a semiconductor device according to an embodiment of the present disclosure.

FIG. 2 shows a semiconductor device according to an embodiment of the present disclosure.

FIG. 3 shows a package according to an embodiment of the present disclosure.

FIG. 4 shows a semiconductor apparatus according to an embodiment of the present disclosure.

FIG. 5 shows a flowchart of a method for fabricating a semiconductor device according to an embodiment of the present disclosure.

FIG. 6 shows a partial elemental concentration distribution of a semiconductor device according to an embodiment of the present disclosure.

### DETAILED DESCRIPTION OF THE EMBODIMENTS

In this application, unless otherwise specified, the general formula AlGaN is represented as AlₐGa₍₁₋ₐ₎N, 0≤a≤1; the general formula InGaN is represented as In_{b}Ga_{(1-b)}N, 0≤b≤1; and the general formula AlInGaN is represented as Al_{c}In_{d}Ga_{(1-c-d)}N, 0≤c≤1 and 0≤d≤1. Adjusting the compositions can achieve different objectives, for example, tuning energy levels or adjusting the dominant emission wavelength of the light-emitting device.

In the present disclosure, unless otherwise stated, the expressions “a to b” or “a-b” defining a specific numerical range are defined as “≥a and ≤b.” The term “thickness” refers to the maximum thickness measured along the normal direction of the semiconductor device. For example, in the expression “the base layer has a first thickness T1,” the first thickness T1 refers to the maximum thickness of the base layer measured along a normal direction of the semiconductor device.

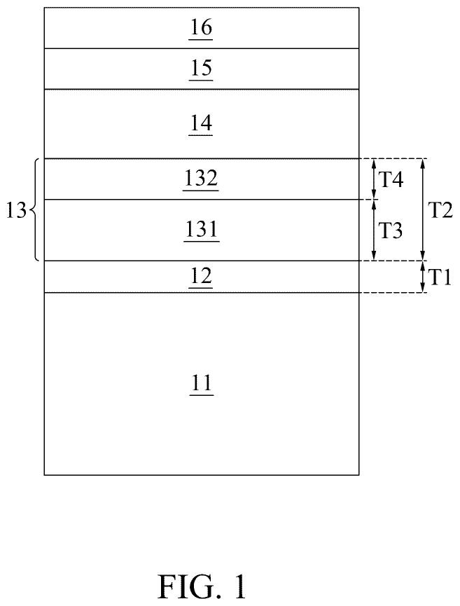

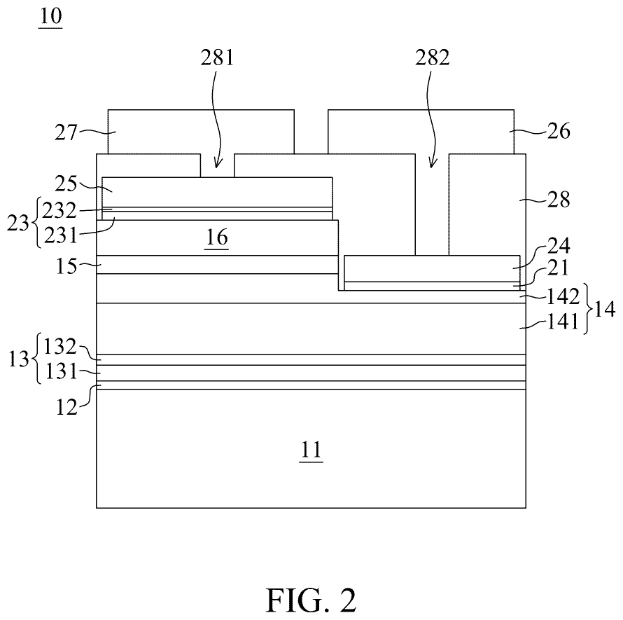

FIG. 1 and FIG. 2 show a semiconductor structure of a semiconductor device 10 according to an embodiment of the present disclosure. As shown in FIG. 1, the semiconductor structure includes a base layer 12, a first semiconductor structure 14 disposed on the base layer 12, and a transition structure 13 disposed between the base layer 12 and the first semiconductor structure 14. The base layer 12 includes nitrogen and aluminum. The transition structure 13 includes a first transition layer 131. The first semiconductor structure 14 includes AlₓGa₁₋ₓN, and the first transition layer 131 includes Al_{y1}Ga_{1-y1}N, 0<x<1 and y1>x. The base layer 12 has a first thickness T1, the transition structure 13 has a second thickness T2, T2>T1.

In a comparative example, the first semiconductor structure 14 is formed on the base layer 12. The base layer 12 may have a first thickness T1 greater than 3 μm to achieve a relatively low epitaxial defect density. However, a thicker first thickness T1 of the base layer 12 may require a longer formation time, thereby increasing the manufacturing cost of the semiconductor device 10. In contrast, in some embodiments of the present disclosure, the base layer 12 has a smaller first thickness T1 while maintaining a sufficiently low epitaxial defect density, for example, by performing high-temperature thermal annealing on the base layer 12 to achieve this effect. The transition structure 13 is used to counteract or reduce stress generated in the base layer 12 due to high-temperature thermal annealing, such as excessive compressive stress. In embodiments, the base layer 12 has a thinner thickness than those of conventional structures, which can reduce the formation time and thus lower the manufacturing cost of the semiconductor device. The first thickness T1 of the base layer 12 may be between 0.1 μm and 3 μm. In some embodiments, the first thickness T1 of the base layer 12 may be 0.15 μm, 0.2 μm, 0.25 μm, 0.3 μm, 0.4 μm, 0.5 μm, 0.6 μm, or 0.8 μm. If the first thickness T1 of the base layer 12 is too large (e.g., greater than 3 μm), the cost-saving effect becomes insignificant. If the first thickness T1 of the base layer 12 is too small (e.g., less than 0.1 μm), an excessively high defect density may be formed in the base layer 12.

In some embodiments, the semiconductor device may further optionally include a substrate 11 disposed under the base layer 12. In some embodiments, the substrate 11 may include silicon, silicon carbide (SiC), aluminum oxide (Al₂O₃), aluminum nitride (AlN), gallium nitride (GaN), or combinations of the foregoing materials. In some embodiments, the substrate 11 may include sapphire. The substrate 11 may be a bulk layer or has multiple sublayers. In some embodiments, the substrate 11 may have a patterned or planar surface.

The base layer 12 may include elements other than nitrogen and aluminum. In some embodiments, the base layer 12 may optionally further include oxygen. In some embodiments, the oxygen content in the base layer 12 may decrease along a direction from the substrate 11 toward the transition structure 13. In some embodiments, the base layer 12 may comprise aluminum nitride or aluminum oxynitride.

The base layer 12, the transition structure 13, the first semiconductor structure 14, and other semiconductor layers of the semiconductor device may be formed on the substrate 11 by any proper method, such as a metal-organic chemical vapor deposition (MOCVD) process, a hydride vapor phase epitaxy (HVPE) process, a molecular beam epitaxy (MBE) process, a physical vapor deposition (PVD) process, an atomic layer deposition (ALD) process, and/or a liquid-phase epitaxy (LPE) process. In some embodiments, the base layer 12 may be subjected to a high-temperature thermal annealing process.

In some embodiments, the transition structure 13 may be in direct contact with the base layer 12, as shown in FIG. 1. The second thickness T2 of the transition structure 13 may be greater than the first thickness T1 of the base layer 12. In some embodiments, the second thickness T2 of the transition structure 13 may be between 0.15 μm and 6 μm. In some embodiments, the second thickness T2 of the transition structure 13 may be 0.2 μm, 0.25 μm, 0.3 μm, 0.35 μm, 0.4 μm, 0.45 μm, 0.5 μm, 0.6 μm, 1 μm, 1.5 μm, 2 μm, 2.5 μm, 3 μm, 4 μm, or 5 μm.

In some embodiments, the ratio of the second thickness T2 to the first thickness T1 may be between 1.5 and 6. That is, the ratio T2/T1 may satisfy the following relationship: 6≥T2/T1>1.5. In some embodiments, the ratio T2/T1 may be 2.85, 3, 4, or 5. If the ratio of the second thickness T2 to the first thickness T1 is too high (e.g., greater than 6), the forward voltage (Vf) of the semiconductor device 10 becomes too high. If the ratio of the second thickness T2 to the first thickness T1 is too low (e.g., lower than 1.5), the stress generated in the base layer 12 due to high-temperature thermal annealing cannot be effectively released, thereby degrading the quality of the subsequently formed first semiconductor structure 14 and other semiconductor layers.

In some embodiments, the transition structure 13 is undoped or unintentionally doped. Here, “unintentionally doped” means that the concentration of elements other than nitrogen, aluminum, and gallium in the transition structure 13 is less than 1.0×10¹⁷ atoms/cm³.

The transition structure 13 may include a first transition layer 131. In some embodiments, the first transition layer 131 may be in direct contact with the base layer 12, as shown in FIG. 1.

The first transition layer 131 may include Al_{y1}Ga_{1-y1}N, 0<y1≤1. In some embodiments, y1 is between 0.85 to 0.99. In some embodiments, y1 is 0.86, 0.87, 0.89, 0.91, 0.93, 0.95, 0.94, or 0.96.

In some embodiments, the transition structure 13 may further optionally include a second transition layer 132 disposed on the first transition layer 131. In some embodiments, the second transition layer 132 may be in direct contact with the first transition layer 131, as shown in FIG. 1. The second transition layer 132 may include Al_{y2}Ga_{1-y2}N, 0<y2≤1 and y2>x. In some embodiments, y2 is between 0.85 and 0.99. In some embodiments, y2 is 0.86, 0.87, 0.89, 0.91, 0.93, 0.95, 0.94, or 0.96. y1 and y2 may be the same or different. That is, y1 and y2 may satisfy the following relationships: y1=y2, y1<y2, or y1>y2.

In some embodiments, the third thickness T3 of the first transition layer 131 may be 0.05 μm, 0.1 μm, 0.15 μm, 0.2 μm, 0.25 μm, 0.3 μm, 0.35 μm, 0.4 μm, 0.8 μm, 1 μm, 1.5 μm, 2 μm, 2.5 μm, 3 μm, or 4 μm. In some embodiments, the fourth thickness T4 of the second transition layer 132 may be between T2 to T3.

The third thickness T3 of the first transition layer 131 and the fourth thickness T4 of the second transition layer 132 may be the same or different. In some embodiments, the third thickness T3 of the first transition layer 131 may be greater than the fourth thickness T4 of the second transition layer 132. In some embodiments, the third thickness T3 of the first transition layer 131 may be 1.5-3.5 times the fourth thickness T4 of the second transition layer 132, for example, 1.7, 1.9, 2.0, 2.2, 2.3, 2.5, or 2.7.

In some embodiments, the second transition layer 132 has a lower defect density than the first transition layer 131. In specific, in an unit area, the number of epitaxial defects in the second transition layer 132 is less than that in the first transition layer 131.

FIG. 2 shows a semiconductor device 10 according to an embodiment of the present disclosure. As shown in FIG. 1 and FIG. 2, in some embodiments, the semiconductor device 10 of the present disclosure may further include an active region 15 and a second semiconductor structure 16 disposed on the first semiconductor structure 14. In some embodiments, the first semiconductor structure 14 and the second semiconductor structure 16 may serve as confinement layers, carrier supply layers, or contact layers. The active region 15 may serve as a light-emitting structure. The first semiconductor structure 14 and the second semiconductor structure 16 may respectively include dopants to supply carriers of different electrical properties. The dopants may include magnesium, silicon, germanium, zinc, or combinations thereof. For example, the first semiconductor structure 14 includes an n-type semiconductor layer and the second semiconductor structure 16 includes a p-type semiconductor layer to provide electrons and holes, respectively; or the first semiconductor structure 14 includes a p-type semiconductor layer and the second semiconductor structure 16 includes an n-type semiconductor layer to provide holes and electrons, respectively. The first semiconductor structure 14, the active region 15, and the second semiconductor structure 16 may include the same group III-V compound semiconductor materials, such as InGaN, AlGaN, or AlInGaN.

When the semiconductor device 10 is a light-emitting device, the wavelength of light emitted by the semiconductor device 10 depends on the material composition of the active region 15. When the active region 15 includes InGaN, the active region 15 may emit blue light with a peak wavelength substantially between 400 nm and 490 nm, cyan light with a peak wavelength substantially between 490 nm and 530 nm, or green light with a peak wavelength substantially between 530 nm and 570 nm. When the active region 15 includes AlGaN, the active region 15 may emit mid-wave ultraviolet light (UV-B) and short-wave ultraviolet light (UV-C) with peak wavelengths substantially between 100 nm and 320 nm. When the active region 15 includes AlInGaN, the active region 15 may emit near-ultraviolet light (UV-A) with peak wavelengths substantially between 420 nm and 320 nm.

In some embodiments, the material of the active region 15 may be an i-type, p-type, or n-type semiconductor. In some embodiments, the semiconductor structure may include a single heterostructure, a double heterostructure, a single quantum well structure, or a multiple quantum well (MQW) structure. In some embodiments, the active region 15 includes one or a plurality of quantum well layers and one or a plurality of barrier layers alternately stacked. One quantum well layer and one barrier layer constitute a quantum pair. In one embodiment, multiple quantum pairs may have the same or different material compositions and energy barriers. For example, the material composition of the quantum well layer or barrier layer of the quantum structure near the first semiconductor structure 14 and that near the second semiconductor structure 16 may be the same or different. For example, the aluminum (Al) composition of the quantum well layers of two quantum structures may be the same or different. Alternatively, the thickness of the quantum well layers or barrier layers of the two quantum structures may be the same or different. The two quantum structures may have different dopant properties. For example, the barrier layer of one quantum structure includes an n-type dopant, such as silicon (Si). The barrier layer of the other quantum structure is undoped or unintentionally doped.

In some embodiments, the first semiconductor structure 14 may be directly disposed on the transition structure 13. In some embodiments, one or a plurality of semiconductor layers may be disposed between the first semiconductor structure 14 and the transition structure 13. In the embodiment shown in FIG. 1, the first semiconductor structure 14 may be in direct contact with the transition structure 13. In other embodiments, a buffer structure may be disposed between the first semiconductor structure 14 and the transition structure 13. The aluminum composition of the buffer structure may be between x and y1 (or y2). In some embodiments, the buffer structure may include at least one unintentionally doped AlGaN semiconductor layer or a superlattice structure. The superlattice structure includes two alternately stacked AlGaN sublayers having different aluminum compositions.

The first semiconductor structure 14 may include a single block layer or multiple sublayers. In embodiments where the first semiconductor structure 14 includes multiple sublayers, each sublayer may have a different composition or a different dopant concentration. For example, in the first semiconductor structure 14, the aluminum composition x of the sublayer closest to the transition structure 13 may be greater than the aluminum composition x of other sublayers. In some embodiments, the first semiconductor structure 14 may include a graded layer 141 and optionally include a first contact layer 142. The aluminum composition x of the graded layer 141 may decrease along a direction from the transition structure 13 toward the active region 15. In some embodiments, the aluminum composition x of the graded layer 141 may decrease along a direction from the transition structure 13 toward the active region 15 from 0.7-1 to 0.60-0.64. The graded layer 141 includes dopants (e.g., silicon, germanium), and the dopant concentration may decrease along a direction from the transition structure 13 toward the active region 15. In some embodiments, the dopant concentration of the graded layer 141 may decrease along a direction from the transition structure 13 toward the active region 15 from 1×10¹⁹-1.4×10¹⁹ atoms/cm³ to 6×10¹⁸-1.2×10¹⁹ atoms/cm³. The first contact layer 142 may have a non-graded or fixed aluminum composition, and the aluminum composition x may be 0.6-0.64. The dopant concentration of the first contact layer 142 may be 6×10¹⁸-1.2×10¹⁹ atoms/cm³. In some embodiments, the aluminum composition of the graded layer 141 may be greater than or equal to the aluminum composition of the first contact layer 142.

As shown in FIG. 2, portions of the second semiconductor structure 16 and the active region 15 may be removed to expose the surface of the first contact layer 142. The semiconductor device 10 may further include a first contact electrode 21 disposed on the exposed surface of the first semiconductor structure 14, such as on the first contact layer 142.

In some embodiments, the second semiconductor structure 16 may include Al_{w}Ga_{1-w}N, 0<w≤1, in a specific embodiment, 0.3≤w≤0.85. The second semiconductor structure 16 may include a single block layer or multiple sublayers. In embodiments where the second semiconductor structure 16 includes multiple sublayers, each sublayer may include a different composition or a different dopant concentration. For example, in embodiments where the second semiconductor structure 16 includes multiple sublayers, the sublayers closer to the active region 15 may include higher aluminum composition w, and the sublayers farther from the active region 15 may include higher dopant concentrations (e.g., concentrations of magnesium or zinc). The semiconductor device 10 may further include a second contact electrode 23 disposed on the second semiconductor structure 16. With the above structure, because the semiconductor device 10 of the present disclosure includes a thinner base layer 12, the manufacturing time can be shortened, thereby reducing cost.

The first contact electrode 21 and the second contact electrode 23 may include metals or transparent conductive materials. The first contact electrode 21 and the second contact electrode 23 may include a single block layer or multiple sublayers. In some embodiments, the metals may include any one of nickel (Ni), gold (Au), silver (Ag), aluminum (Al), palladium (Pd), platinum (Pt), vanadium (V), zirconium (Zr), chromium (Cr), rhodium (Rh), titanium (Ti), or alloys of any combination thereof. Transparent conductive materials may include titanium nitride (TiN), indium tin oxide (ITO), indium zinc oxide (IZO), aluminum tin oxide (AlTO), aluminum zinc oxide (AZO), indium gallium oxide (IGO), or any combination thereof. In one embodiment, the first contact electrode 21 may be a metal stack that forms an ohmic contact to the first semiconductor structure 14 by heating. The materials of the first contact electrode 21 may include aluminum, vanadium, titanium, nickel, or chromium. In one embodiment, the second contact electrode 23 formed on the second semiconductor structure 16 may include a transparent conductive layer 231. The transparent conductive layer 231 may include the aforementioned transparent conductive materials or metals such as rhodium or nickel. In addition, a reflective structure 232 may be formed on the transparent conductive layer. The reflective structure 232 may be a metal stack, and the materials of the reflective structure 232 may include silver, aluminum, chromium, nickel, titanium, or platinum. The semiconductor device 10 may further include a first electrode layer 24 and a second electrode layer 25 formed on the first contact electrode 21 and the second contact electrode 23, respectively. The semiconductor device 10 may further include an insulating structure 28 that covers the surfaces of the semiconductor layers of the semiconductor device 10 and has a first opening 281 and a second opening 282 exposing the first electrode layer 24 and the second electrode layer 25. The semiconductor device 10 may further include a first electrode pad 26 and a second electrode pad 27 formed on the insulating structure 28 and electrically connected to the first electrode layer 24 and the second electrode layer 25 through the first opening 281 and the second opening 282, respectively.

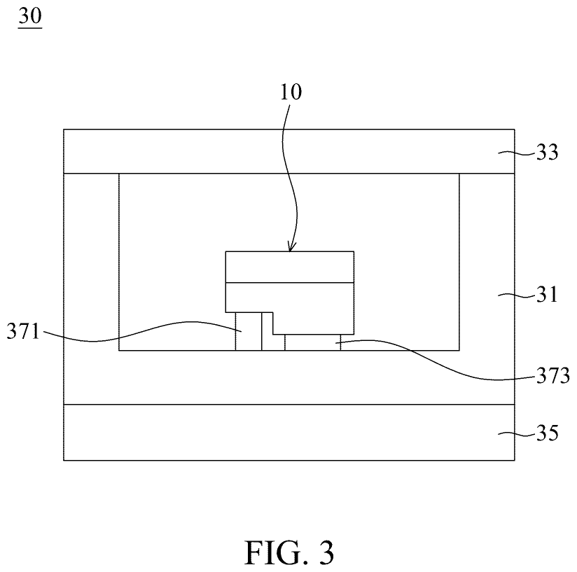

FIG. 3 shows a package 30 including the semiconductor device 10 shown in FIG. 2. As shown in FIG. 3, the package 30 includes a reflective cavity 31, the semiconductor device 10 disposed in the reflective cavity 31, and a light-transmitting body 33 disposed on the semiconductor device 10. In some embodiments, the light-transmitting body 33 may be disposed on the reflective cavity 31 and seal the semiconductor device 10 and in the reflective cavity 31.

In some embodiments, the package 30 may further include a circuit board 35 disposed under the reflective cavity 31. A portion of the reflective cavity 31 is disposed between the circuit board 35 and the semiconductor device 10. In some embodiments, conductive through holes (not shown) may be formed in the reflective cavity 31, and the semiconductor device 10 may be electrically connected to the circuit board 35 via the conductive through holes in the reflective cavity 31 through a first metal interconnect 371 and a second metal interconnect 373.

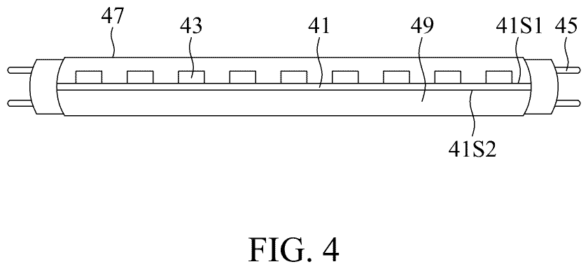

FIG. 4 shows a semiconductor apparatus according to an embodiment of the present disclosure. As shown in FIG. 4, the semiconductor apparatus includes an electrical connection member 41, a plurality of light-emitting units 43 disposed on the electrical connection member 41, and terminals 45 that electrically connect the electrical connection member 41 to an external device (not shown). The light-emitting units 43 may be substantially the same as the semiconductor device 10 shown in FIG. 2 or substantially the same as the semiconductor package 30 shown in FIG. 3. The plurality of light-emitting units 43 may be the same or different from each other. For example, in some embodiments, some of the light-emitting units 43 may be substantially the same as the semiconductor device 10 shown in FIG. 2, while others may be substantially the same as the semiconductor package 30 shown in FIG. 3.

The electrical connection member 41 may include a conductive material having a long plate shape. The electrical connection member 41 may have a first surface 41S1 and a second surface 41S2 opposite the first surface 41S1. The plurality of light-emitting units 43 are disposed on the first surface 41S1 of the electrical connection member 41 and are electrically connected to the electrical connection member 41. In some embodiments, the plurality of light-emitting units 43 may be spatially spaced apart from each other on the first surface 41S1 of the electrical connection member 41. In some embodiments, the plurality of light-emitting units 43 may be closely arranged without spatial gaps on the first surface 41S1 of the electrical connection member 41. The light-emitting units 43 may be electrically connected to an external device through the terminals 45 that are electrically connected to the electrical connection member 41.

The external device may include a circuit board, a power supply, other suitable devices, or any combination thereof. In some embodiments, the external device may include a power supply, which provides electrical power to the light-emitting units 43 through the terminals 45 and the electrical connection member 41.

In some embodiments, the semiconductor apparatus may further include a cover structure 47 disposed on the first surface 41S1 of the electrical connection member 41. The light-emitting units 43 may be disposed between the electrical connection member 41 and the cover structure 47. In some embodiments, the electrical connection member 41 and the cover structure 47 may together seal the light-emitting units 43 to protect the light-emitting units 43. The light emitted by the light-emitting units 43 may pass through the material of the cover structure 47. In some embodiments, the cover structure 47 may include a transparent material.

In some embodiments, the semiconductor apparatus may further include a heat dissipation structure 49 disposed on the second surface 41S2 of the electrical connection member 41 to dissipate heat generated by the light-emitting units 43. The heat dissipation structure 49 may include a heat sink plate, heat dissipation fins, a water-cooling device, or any combination thereof.

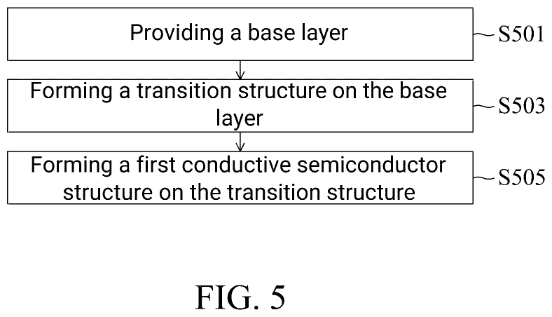

One aspect of the present disclosure provides a method of fabricating a semiconductor device. FIG. 5 is a flowchart of a method for manufacturing a semiconductor device according to an embodiment of the present disclosure. As shown in FIG. 5, the method for manufacturing the semiconductor device includes a step S501 of providing a base layer, a step S503 of forming a transition structure on the base layer, and a step S505 of forming a first semiconductor structure on the transition structure. The method for fabricating the semiconductor device of the present disclosure is further described below with reference to FIG. 1 and FIG. 5.

Step S501 may include a process of forming the base layer 12 on the substrate 11. In some embodiments, the process of forming the base layer 12 may include a metal-organic chemical vapor deposition process, a hydride vapor phase epitaxy process, a molecular beam epitaxy process, a physical vapor deposition process, an atomic layer deposition process, and/or a liquid-phase epitaxy process. In some embodiments, taking the MOCVD process as an example, the substrate 11 (e.g., a sapphire substrate) is placed in a reaction chamber, and an aluminum-containing gas (e.g., trimethylaluminum, TMAl) and a nitrogen-containing gas (e.g., ammonia, NH3) are introduced into the reaction chamber to perform epitaxial growth.

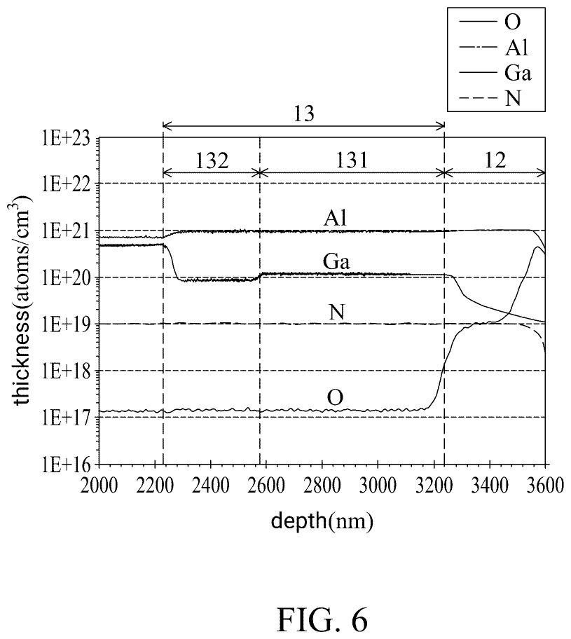

FIG. 6 shows a partial elemental concentration distribution of a semiconductor device according to an embodiment of the present disclosure, in which the base layer 12 and the transition structure 13 are indicated, and the transition structure 13 includes a first transition layer 131 and a second transition layer 132. As shown in FIG. 6, due to the high-temperature thermal annealing process, oxygen in the substrate 11 diffuses into the base layer 12. The oxygen concentration in the base layer 12 is between 1×10¹⁹ and 5×10²⁰ atoms/cm³, and the oxygen content decreases along a direction from the substrate 11 toward the transition structure 13. The concentrations of gallium, aluminum, and nitrogen in FIG. 6 only indicate their distributions within the base layer 12 and the transition structure 13; the actual concentrations do not correspond to the values on the vertical axis. In this embodiment, the gallium concentration in the first transition layer 131 is greater than the gallium concentration in the second transition layer 132.

As shown in FIG. 1, FIG. 5, and FIG. 6, the thickness of the transition structure 13 formed in step S503 may be greater than the thickness of the base layer 12 formed in step S501. Step S503 may include forming the first transition layer 131 on the base layer 12 using group III elements (including aluminum and gallium) and group V elements (including nitrogen), and forming the second transition layer 132 on the first transition layer 131 using group III elements (including aluminum and gallium) and group V elements (including nitrogen).

In some embodiments, taking the MOCVD process as an example, in step S503, the process of forming the transition structure 13 may include placing the substrate 11 into a reaction chamber, and introducing group III element-containing gases and group V element-containing gases into the reaction chamber to form the first transition layer 131 and the second transition layer 132. The film growth rates of the first transition layer 131 and the second transition layer 132 may be adjusted by adjusting the flow rates of the group III element-containing gases and the group V element-containing gases introduced.

The V/III ratio used in forming the first transition layer 131 may be different from the V/III ratio used in forming the second transition layer 132. In some embodiments, the V/III ratio used in forming the second transition layer 132 is higher than the V/III ratio used in forming the first transition layer 131. The distinction between the first transition layer 131 and the second transition layer 132 is that the film growth rate of the first transition layer 131 is greater than that of the second transition layer 132, whereby the first transition layer 131 can be used to release stress, while the second transition layer 132 has a lower epitaxial defect density than the first transition layer 131.

In step S505, the first semiconductor structure 14 may be formed on the transition structure 13. Depending on the manner for forming the transition structure 13, the process of forming the first semiconductor structure 14 may include a metal-organic chemical vapor deposition process, a hydride vapor phase epitaxy process, a molecular beam epitaxy process, a physical vapor deposition process, an atomic layer deposition process, and/or a liquid-phase epitaxy process. The characteristics of the first semiconductor structure 14 formed in step S505 are as described above and thus are not repeated here.

In some embodiments, the method for fabricating a semiconductor device of the present disclosure may further include forming the active region 15 on the first semiconductor structure 14 and forming the second semiconductor structure 16 on the active region 15. The characteristics of the active region 15 and the second semiconductor structure 16 formed in the above steps are as described above and thus are not repeated here. Subsequently, portions of the second semiconductor structure 16 and the active region 15 may be removed, and processes for forming the electrode structures and insulating structures and a dicing process may be performed, thereby forming the semiconductor device 10 of the present disclosure.

The method for manufacturing a semiconductor device of the present disclosure can lower a cost for manufacturing a high-quality semiconductor device. Furthermore, the method for manufacturing a semiconductor device of the present disclosure can produce a semiconductor device having lower forward voltage (Vf), lower electrical resistance, higher light-output, and/or improved reliability.

According to the method for manufacturing a semiconductor device of the present disclosure, the first transition layer 131 in the fabricated semiconductor device helps release stress accumulated in the base layer 12. The second transition layer 132 helps continue to release stress while reducing epitaxial defects, thereby improving the epitaxial quality of subsequent semiconductor layers of the semiconductor device.

Although the embodiments of the present disclosure and their advantages have been described above, it should be understood that those of ordinary skill in the art can make modifications, substitutions, and refinements without departing from the spirit and scope of the present disclosure. In addition, the scope of protection of the present disclosure is not limited to the processes, machines, manufacture, compositions of matter, devices, methods, and steps described in the specific embodiments in the specification. Those of ordinary skill in the art can understand, from the disclosure of some embodiments of the present disclosure, processes, machines, manufacture, compositions of matter, devices, methods, and steps developed currently or in the future, so long as they perform substantially the same functions or achieve substantially the same results in the embodiments described herein, and such may be used according to some embodiments of the present disclosure. Therefore, the scope of protection of the present disclosure includes the foregoing processes, machines, manufacture, compositions of matter, devices, methods, and steps. Moreover, each claim constitutes a separate embodiment, and the scope of protection of the present disclosure also includes combinations of the respective claims and embodiments.

1. A semiconductor device comprising:
a base layer comprising nitrogen and aluminum;
a first semiconductor structure disposed on the base layer and comprising AlₓGa₁₋ₓN, wherein 0<x <1; and
a transition structure disposed between the base layer and the first semiconductor structure and comprising a first transition layer comprising Al_{y1}Ga_{1-y1}N, wherein y1>X,
wherein the base layer has a first thickness T1, the transition structure has a second thickness T2, and T2>T1.

2. The semiconductor device of claim 1, wherein 6>T2/T1≥1.5.

3. The semiconductor device of claim 1, wherein y1 is between 0.85 and 0.99.

4. The semiconductor device of claim 1, wherein the transition structure further comprises:
a second transition layer disposed between the first transition layer and the first semiconductor structure and comprising Al_{y2}Ga_{1-y2}N;
wherein the second transition layer has a lower defect density than the first transition layer.

5. The semiconductor device of claim 4, wherein y1=y2.

6. The semiconductor device of claim 4, wherein y1<y2.

7. The semiconductor device of claim 4, wherein y1>y2.

8. The semiconductor device of claim 4, wherein the first transition layer comprises a third thickness, the second transition layer comprises a fourth thickness less than the third thickness.

9. The semiconductor device of claim 8, wherein the third thickness of the first transition layer is 1.5 to 3.5 times the fourth thickness of the second transition layer.

10. The semiconductor device of claim 1, wherein the transition structure is undoped or unintentionally doped.

11. The semiconductor device of claim 1, wherein the transition structure has a thickness of 0.2 μm to 5 μm.

12. The semiconductor device of claim 1, further comprising an active region on the first semiconductor structure.

13. The semiconductor device of claim 12, further comprising a second semiconductor structure on the active region, wherein the second semiconductor structure comprises Al_{w}Ga_{1-w}N, wherein 0<w≤1.

14. The semiconductor device of claim 12, wherein the first semiconductor structure comprises a graded layer having a graded aluminum composition.

15. The semiconductor device of claim 14, wherein the aluminum composition of the graded layer decreases along a direction from the transition structure toward the active region.

16. The semiconductor device of claim 14, wherein the graded layer comprises a dopant with a doping concentration decreasing from the transition structure toward the active region.

17. The semiconductor device of claim 14, wherein the first semiconductor structure further comprises a first contact layer disposed on the graded layer.

18. The semiconductor device of claim 1, wherein the base layer further comprises oxygen.

19. The semiconductor device of claim 1, further comprising a substrate, wherein the base layer is disposed between the substrate and the transition structure.

20. The semiconductor device of claim 1, wherein the first semiconductor structure is in direct contact with the transition structure.
